(19) United States
(12) Patent Application Publication
(10) Pub. No.: US 2026/0239919 A1
(43) Pub. Date: Aug. 13, 2026

(54) REAL-TIME SENSOR PROCESSING TO MEASURE SUBSTRATE OFFSETS AND APPLY CORRECTIONS TO CHAMBER MEMBER POSITIONING

(71) Applicant: Applied Materials, Inc., Santa Clara, CA (US)

(72) Inventors: Hyun Joo Lee, Seoul (KR); Dmitry Lubomirsky, Cupertino, CA (US); Pranav Vijay Gadre, Sunnyvale, CA (US); Shekhar Athani, Bengaluru (IN); Ellie Yieh, San Jose, CA (US)

(21) Appl. No.: 19/049,880

(22) Filed: Feb. 10, 2025

(51) Int. Cl. H01L 21/68; C23C 16/458; C23C 16/52; G01B 11/14

(52) U.S. Cl. CPC H10P 72/53; C23C 16/4583; C23C 16/52; G01B 11/14

(57) ABSTRACT

A system includes a chamber having a substrate support and an upper member having an upper member surface positioned within the chamber that is vertically movable relative to the substrate support. One or more sensors each measure an edge location of a substrate on the substrate support. A linear stage assembly is coupled to the upper member and first and second motors operatively are coupled to a first side of a first linear stage and a second side of a second linear stage of a set of linear stages to move the linear stage assembly in a first direction and in a second direction. Control logic receives the edge location, determines an offset value of the substrate relative to the edge location, and controls at least one of the first or second motor using the offset value to center the upper member surface over the substrate.

### TECHNICAL FIELD

Aspects and embodiments of the disclosure relate to processing chamber member movements, and more specifically, to systems and methods for real-time sensor processing to measure substrate offsets and apply corrections to chamber member positioning.

### BACKGROUND

A processing chamber has various chamber members, including an upper member positioned above a substrate. The upper member may be a heater used to provide controlled thermal energy to materials or components within a processing chamber so that a substrate can be processed such as via deposition, etching, cleaning, or the like, to include edge or bevel deposition. If the heater or other upper member (such as a showerhead) is comparable or smaller in diameter to the substrate, the substrate is centered to ensure that the edges are processed properly. For example, if the heater is the same diameter as the substrate and is not properly centered above the substrate, the edge (or bevel) of the substrate will not receive the same amount of thermal energy, and the deposited film on the substrate edge will not be uniform. This lack of uniformity can decrease device performance and yield from the fabrication process.

### SUMMARY

The following is a simplified summary of the disclosure in order to provide a basic understanding of some embodiments of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

Some embodiments described herein cover a system for processing substrates. For example, a system according to one embodiment includes a chamber with a substrate support, one or more sensors, an upper member with an upper member surface positioned within the chamber, a linear stage assembly coupled to the heater, and control logic. The upper member may be moveable up and down relative to the substrate support. The one or more sensors may each be configured to measure an edge location of a substrate placed on the substrate support. The linear stage may include a set of linear stages, a first motor, and a second motor. The first motor may be operatively coupled to a first side of the set of linear stages to move a first linear stage of the set of linear stages in a first direction. The second motor may be operatively coupled to a second side of the set of linear stages to move a second linear stage of the set of linear stages in a second direction. The first motor, the second motor, and/or the one or more sensors may be operatively coupled to control logic, which may: receive the edge location from the one or more sensors; determine, based on a radius of the substrate, an offset value of the substrate relative to the edge location; and control, using the offset value, the first motor and/or the second motor to center the upper member surface over the substrate.

Some embodiments described herein cover a method for processing substrates. For example, a method according to one embodiment includes receiving, by a processing device, a radius of a substrate placed on a substrate support of a chamber. The processing device may be coupled to a first motor and a second motor of a linear stage assembly that is operatively coupled to an upper member. An upper member surface may be movable up and down relative to the substrate support. The method includes receiving from one or more sensors that image edges of the substrate, at least one edge location of the substrate. The method includes determining an offset value of the substrate based on the radius and the edge location of the substrate. The method includes causing, by the processing device, based on the offset value, the first motor and/or the second motor to move the linear stage assembly in a first direction and/or a second direction, respectively, to center the upper member surface over the substrate.

Some embodiments described herein cover a system for processing substrates. For example, a system according to one embodiment includes a chamber with a showerhead, one or more sensors positioned outside of the chamber, a heater with a radiation surface positioned within the chamber, a linear stage assembly coupled to the heater, and control logic. The heater may be moveable up and down relative to the showerhead. The one or more sensors may each be configured to measure an edge location of a substrate placed on the radiation surface. The linear stage assembly may include a set of linear stages, a first motor, and a second motor. The first motor may be operatively coupled to a first side of the set of linear stages to move a first linear stage of the set of linear stages in a first direction. The second motor may be operatively coupled to a second side of the set of linear stages to move a second linear stage of the set of linear stages in a second direction. The first motor, the second motor, and/or the one or more sensors may be operatively coupled to control logic, which may: receive the edge location from the one or more sensors; determine, based on a radius of the substrate, an offset value of the substrate relative to the edge location; and control, using the offset value, the first motor and/or the second motor to center the substrate below the showerhead.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one, but can make reference to multiple embodiments.

FIG. 1A is a schematic block diagram of an example processing system, including a linear stage assembly, according to some embodiments.

FIG. 1B is a cross-section view of the example processing system, including the linear stage assembly, according to some embodiments.

FIG. 1C is a perspective view of an example upper member lift and the linear stage assembly according to some embodiments.

FIG. 1D is a perspective cross-section view of the example upper member lift and the linear stage assembly according to some embodiments.

FIG. 2A is a perspective view of an upper member, including the linear stage assembly, according to some embodiments.

FIG. 2B is a perspective view of the linear stage assembly according to some embodiments.

FIG. 2C is a front perspective view of the linear stage assembly according to some embodiments.

FIG. 3 is a cross-section view of a camera system according to some embodiments.

FIG. 4A is a cross-section view of a portion of the example processing system with a substrate elevated below the upper member, according to some embodiments.

FIG. 4B is the cross-section view of the portion of the example processing system with the substrate lowered on a substrate support according to some embodiments.

FIG. 4C is a zoomed-in view of a lift pin retracting below the substrate support according to some embodiments.

FIG. 4D is a zoomed-in view of a view port that provides an imaging channel to an edge of the substrate support and example image data of off-centered edge locations of the substrate according to some embodiments.

FIG. 5A is a cross-section view of an example processing system with a heater and substrate support combination positioned below a showerhead and one or more sensors positioned above the showerhead according to some embodiments.

FIG. 5B is a cross-section view of an example processing system with a heater and substrate support combination positioned below a showerhead and one or more sensors positioned below the heater and substrate support combination according to some embodiments.

FIG. 6A is a flow chart of an example method for determining an offset for use in controlling a linear stage assembly to center an upper member above a substrate according to some embodiments.

FIG. 6B is a flow chart of an example method for determining the offset for use in controlling the linear stage assembly to center a heater and substrate support combination below a showerhead according to some embodiments.

### DETAILED DESCRIPTION OF EMBODIMENTS

Embodiments described herein are related to real-time sensor processing to measure substrate offsets and apply corrections to upper member (e.g., heater or showerhead) positioning, which resolves the above-mentioned deficiencies in current substrate processing systems. In embodiments, a substrate has a bevel around the outer edge of the substrate that can be processed according to certain deposition applications. For example, a lithography process is sensitive to deposition on the substrate bevel. Further, for high stress film deposition applications, the high stress film itself can cause slip defects. A slip defect is a type of structural flaw that occurs in a substrate when a part of the substrate's crystal lattice is displaced relative to another part of the substrate's crystal lattice along crystallographic planes and directions. The shear stress from the high stress film can be sufficient to cause such slip defects. To alleviate some of the shear stress from the high stress film, the substrate may first undergo a bevel deposition process, during which film deposition occurs on a small outer perimeter of the substrate (e.g., about 0.5 mm from the edge of the substrate). In such exacting deposition processes, concentricity constraints are often implemented.

The bevel deposition process and other deposition processes implement concentricity constraints, in which the alignment and uniformity of the various features created during fabrication are focused around the central axis of a substrate. Concentricity refers to the degree to which multiple circular objects have the same center. For example, concentricity constraints may be met when the components are sufficiently centered, such that a center of a substrate is aligned with the center of an upper member (e.g., showerhead) and/or with a lower member (e.g., heater) of the chamber. When concentricity constraints are implemented, the constraints may be controlled through assembly tolerances of an upper member (e.g., a showerhead in a chamber) and/or of the lower member (e.g., a heater). However, thermal expansion of components, substrate transfer, differences between individual chambers, and other factors may cause concentricity to vary between chambers.

Some deposition processes may include deposition on the bevel of a substrate (e.g., bevel deposition) within strict dimensional tolerances. This is challenging, especially when the heater is approximately the same size as the substrate (e.g., the heater or upper member does not extend beyond the bevel or edge of the substrate). If the bevel of the substrate is not within the strict dimensional tolerances from the upper member (e.g., the heater or a showerhead), the deposition of the entire substrate may suffer from defects to the deposition layer on the substrate bevel. For example, if the substrate is undergoing radio frequency (RF) plasma etching and the upper member acts as an electrode, the plasma profile on the substrate may be offset if the upper member is not properly centered above the substrate. Such defects can result in waste, as the substrate either has an uneven deposition or is unusable due to these slip defects. In some bevel depositions, operators manually center the substrate with reference to the heater across multiple substrate processing iterations until the processed substrates have acceptably low defects, which reduces performance and is susceptible to user error.

The devices, systems, and methods disclosed herein address these tight dimensional features in terms of the substrate being centered with reference to the heater and/or showerhead during bevel-based processing by employing sensors (e.g., camera systems) to measure substrate offsets and apply corrections to heater and/or showerhead positioning accordingly. Although the present embodiments are especially helpful for bevel-based processing, the present embodiments can also be employed in normal substate processing. In some embodiments, a system includes a chamber with a substrate support, one or more sensors configured to measure one or more edge locations of a substrate placed on the substrate support, an upper member (e.g., a heater) with an upper member surface (e.g., a radiation surface of the heater) positioned within the chamber and vertically moveable relative to the substrate support, a linear stage assembly coupled to the upper member, and control logic.

In some embodiments, the linear stage assembly includes a set of linear stages, a first motor, and a second motor. The first motor may be operatively coupled to a first side of the set of linear stages to move a first linear stage of the set of linear stages in a first direction (e.g., X direction). The second motor may be operatively coupled to a second side of the set of linear stages to move a second linear stage of the set of linear stages in a second direction (e.g., Y direction). The second side may be adjacent to the first side of the set of linear stages and the first direction may be orthogonal to the second direction. The first motor, the second motor, and/or the one or more sensors may be operatively coupled to control logic, which may receive the edge location from the one or more sensors and determine, based on a radius of the substrate, an offset value of the substrate relative to the edge location. The control logic may then control, using the offset value, the first motor and/or the second motor to center the radiation surface over the substrate. Similar operations may be employed to center a showerhead with reference to a substrate in other embodiments.

The systems, devices, and methods disclosed herein have advantages over conventional solutions such as iterative manual centering. By causing small edge adjustments in the heater (e.g., upper member) itself, the present disclosure may ensure that the heater (or another member of a chamber such as a showerhead) is aligned with the substrate and will concentrically reach the bevel of the substrate. The present disclosure may provide an even and consistent deposition processing over the entire substrate (including the bevel) by centering the heater (or another member of a chamber) above the substrate, which is particularly useful when the heater is approximately the same size as the substrate.

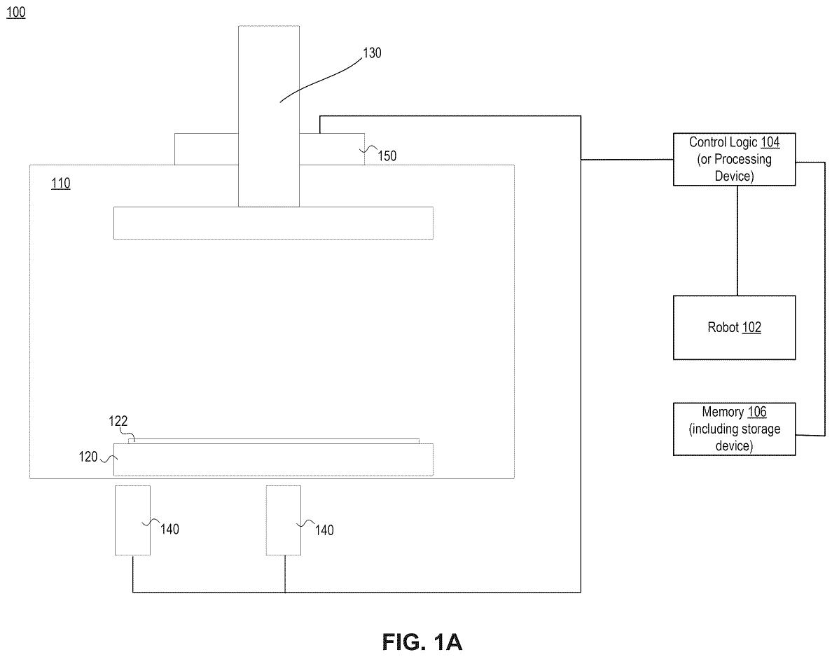

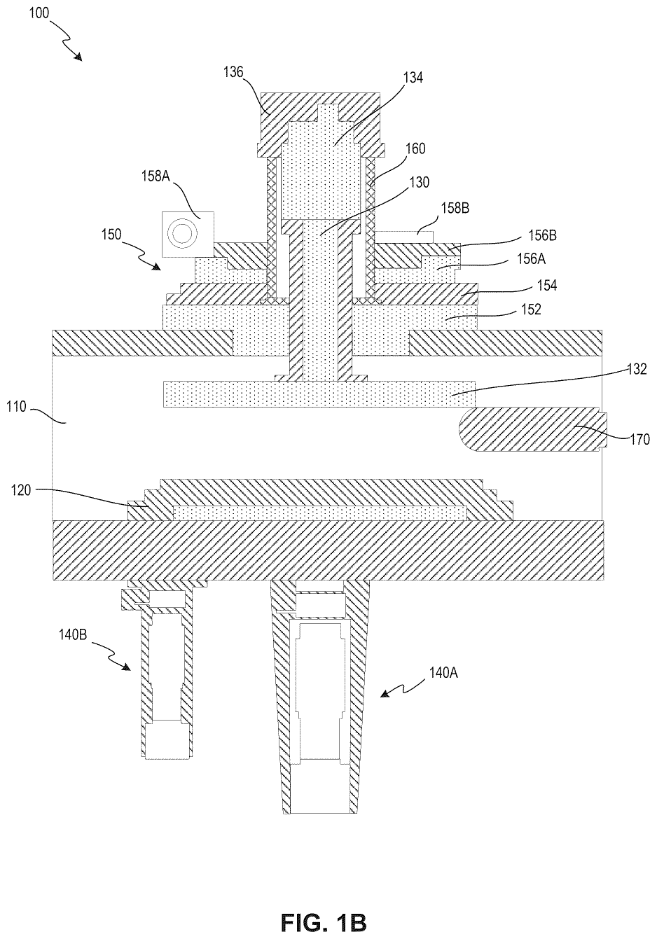

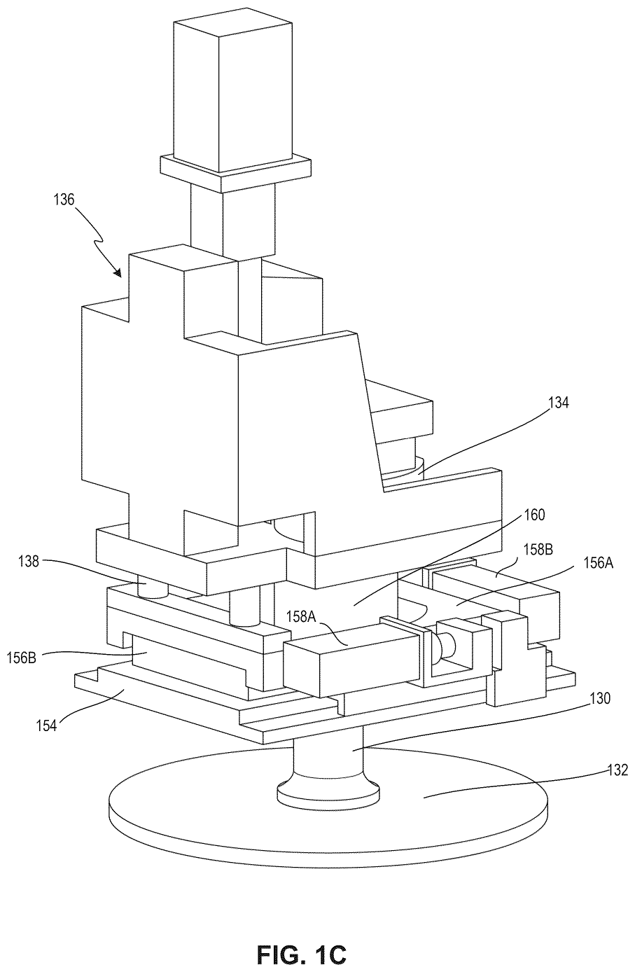

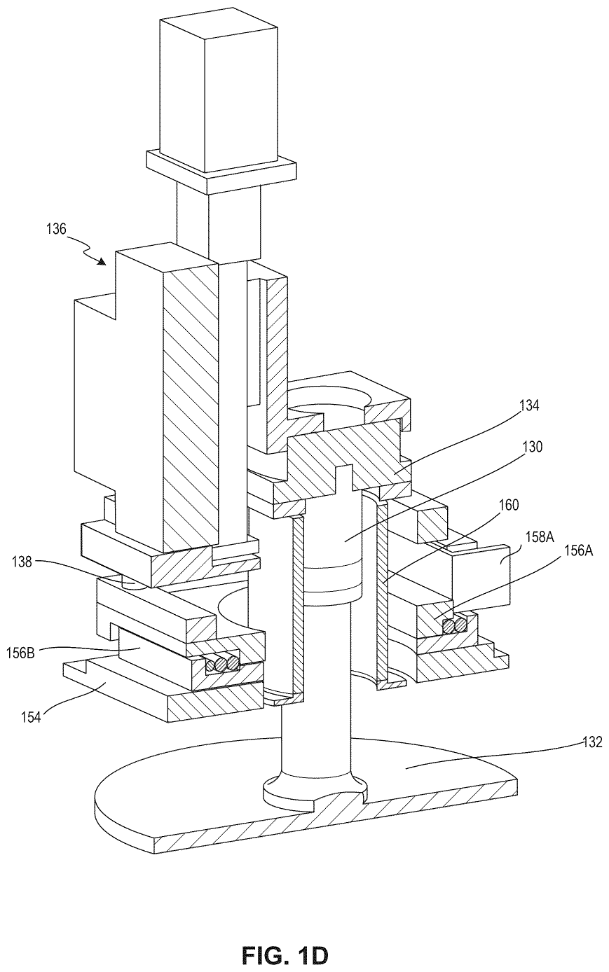

FIG. 1A is a schematic block diagram of an example processing system 100, including a linear stage assembly 150, according to some embodiments. In some embodiments, the processing system 100 includes a robot 102, a chamber 110, and control logic 104 (or processing device) configured to execute instructions or otherwise control the robot 102 and operations performed within the chamber 110, as will be described in detail. In some embodiments, the processing system 100 includes memory 106 coupled to the control logic 104, which can include volatile memory and optionally also non-volatile memory, such as a storage device. For example, the memory 106 can be a non-transitory computer-readable storage medium storing instructions, which when executed by the processing device (e.g., the control logic 104), cause the processing device to perform particular operations that will be discussed herein.

In some embodiments, the robot 102 (which may include multiple robots, which may perform a handoff of a substrate 122, such as through a via or load lock station) transfers each substrate 122 through a transfer chamber, and through a slit valve or door of the chamber 110, and places the substrate 122 onto a substrate support 120 located inside of the chamber 110. In some embodiments, the robot 102 that places the substrate 122 into the chamber 110 may be a robot of a transfer chamber.

In some embodiments, the processing system 100 includes a substrate support 120 onto which a substrate 122 is placed by the robot 102, a heater 130 (e.g., an upper member) configured to move vertically relative to the substrate support 120 and the substrate 122, a linear stage assembly 150 coupled to the heater 130 and configured to move the heater 130 in a first and/or second direction (e.g., X and/or Y direction, respectively). In embodiments, the processing system 100 further includes one or more camera systems 140 configured to provide edge location data to control logic 104, which then instructs the linear stage assembly 150 to move in a first and/or second direction. In varying embodiments, the substrate support 120 can be a susceptor (e.g., which may include a susceptor pocket), a chuck (e.g., such as an electrostatic chuck a vacuum chuck, etc.), or other type of substrate support that is adapted to rotate or spin. The substrate 122 can be a wafer or other type of media (e.g., a plate such as a glass plate, which may have a circular shape in embodiments) capable of being processed into dies, such as for integrated circuits, transistors, photonic devices, radio frequency (RF) devices, or the like.

In some embodiments, the heater 130 provides thermal energy to regulate the temperature of the substrate 122 or gases used in the chamber 110 to ensure proper material reactions and uniformity during substrate processing. The gases used in the chamber may be a reactive gas (e.g., precursors) for chemical vapor deposition (CVD), atomic or molecular beams of desired material for molecular beam epitaxy (MBE), or other compounds for other types of film growth or epitaxial deposition on the substrate 122.

In disclosed embodiments, the camera systems 140 (including one or more sensors) are positioned outside of (e.g., above and/or below) the chamber 110. In some embodiments, the control logic 104 is coupled to the camera systems 140 to receive images of the edge locations of the substrate 122 captured by the camera systems 140.

In some embodiments, the linear stage assembly 150 is operatively coupled to the heater 130 and includes a first motor to move the linear stage assembly 150 in a first direction (e.g., X direction) and a second motor to move the linear stage assembly 150 in a second direction (e.g., Y direction). In disclosed embodiments, the control logic 104 is coupled to the first motor and/or the second motor to control the first motor and/or the second motor to center the heater 130 over the substrate 122.

FIG. 1B is a cross-section view of the example processing system 100, including a linear stage assembly 150, according to some embodiments. FIG. 1C is a perspective view of an example upper member lift (e.g., a heater lift 136) and the linear stage assembly 150 according to some embodiments. FIG. 1D is a perspective cross-section view of the example heater lift 136 and the linear stage assembly 150 according to some embodiments. In such embodiments, the processing system 100 includes the chamber 110, the substrate support 120, the heater 130, one or more camera systems 140A and 140B, the heater lift 136, a bellow 160, and a slit valve 170.

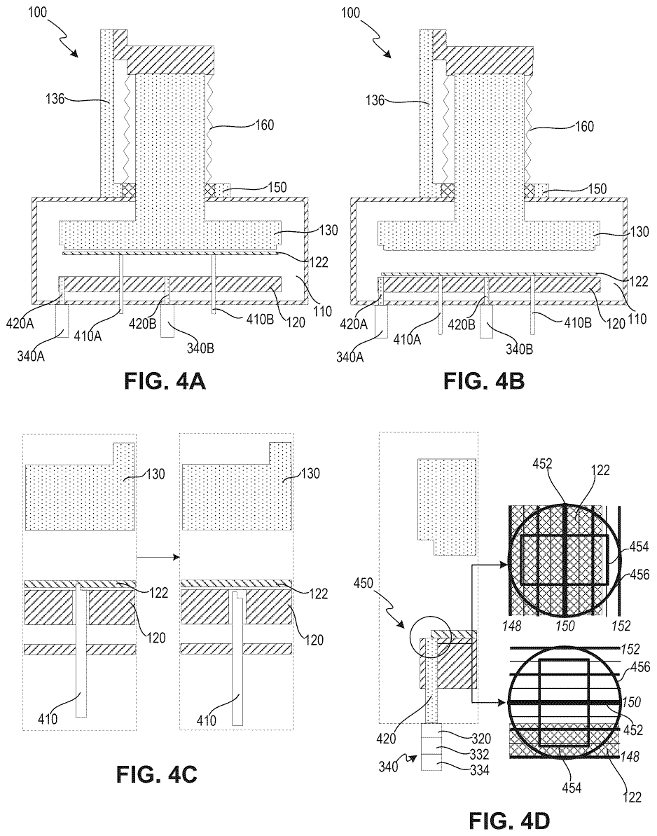

In some embodiments, the chamber 110 includes the substrate support 120 on which a substrate (e.g., the substrate 122 of FIG. 1A) is placed for processing. The substrate support 120 may include one or more lift pins (e.g., the lift pins 410A-B of FIGS. 4A-4C) configured to be lifted up and down to position the substrate on the substrate support 120. At least a portion of the substrate support can include (or be integrated with) a showerhead from which processing gases are forced to deposit a thin film on the bevel or edge of the substrate. The chamber 110 may further include the heater 130, of which at least a portion of the heater 130 is configured to be disposed in the chamber 110 above the substrate support 120. The chamber 110 and other components disposed within the chamber 110 (e.g., the substrate support 120, the heater 130) may be in a vacuum, e.g., an environment of very low pressure to prevent contamination and control the behavior of the gases and materials during processing.

In some embodiments, the heater 130 includes an upper member surface (e.g., a radiation surface 132) positioned within the chamber 110. The heater 130 may be movable up and down relative to the substrate support 120 (e.g., the heater 130 may be raised to move away from the substrate support 120 and lowered to move toward the substrate support 120). The heater 130 may further include an upper member adapter (e.g., a heater adapter 134), which may act as an interface between and be operatively coupled to the heater 130 and the heater lift 136. In embodiments, raising the heater lift 136 up causes the heater adapter 134 to be raised, which causes the heater 130 and the radiation surface 132 to raise.

In some embodiments, the heater adapter 134 is further coupled to a bellow 160, which is configured to encase the heater 130 and maintain the heater 130 at vacuum (e.g., at the same pressure as a chamber, such as the chamber 110 of FIG. 1A). The bellow 160 may be a semi-flexible member configured to move in the up or down direction (e.g., along the Z axis direction) that surrounds the heater 130 and attaches to both a lid 152 of the chamber 110 and the heater adapter 134. The semi-flexible characteristic of the bellow 160 may further allow the bellow 160 to move relatively small distances in a side-to-side direction (e.g., along the X and/or Y axis direction). The semi-flexible characteristic of the bellow 160 may further allow the heater 130 to move relatively small distances in a side-to-side direction responsive to the linear stage assembly 150 moving the heater lift 136. The bellow 160 may be configured to prevent contamination of the chamber 110 from the linear stage assembly 150 and other components that reside at atmospheric pressure outside of the chamber 110. In particular, FIG. 1D illustrates how the bellow 160 may encase the heater 130 and isolate the heater 130 from the linear stage assembly 150, thus maintaining a vacuum around the heater 130 and within the chamber 110.

In some embodiments, the linear stage assembly 150 is coupled to the heater lift 136 via a linear stage attachment 138 and is configured to move within a single plane such as in a first direction (e.g., along an X axis) and in a second direction (e.g., along a Y axis direction). By moving a set of linear stages of the linear stage assembly 150, the control logic 104 is able to cause discrete movements in the heater 130 to center the heater 130 above the substrate.

For example, the linear stage assembly 150 may include a set of linear stages including a first linear stage 156A configured to move the heater lift 136 in the first direction and a second linear stage 156B configured to move the heater lift 136 in the second direction. The linear stage 150 can further include a base plate 154 that can be attached to the lid 152. In some embodiments, the second linear stage 156B is movably coupled between the first linear stage 156A and the base plate 154 (e.g., the second linear stage 156B may move along the base plate 154 and the first linear stage 156A). By moving the first linear stage 156A in the first direction and/or the second linear stage 156B in the second direction, the heater lift 136 moves in a substantially similar manner in both the first and second directions, which causes the heater 130 to move in both the first and second directions to center above the substrate. In some embodiments, the linear stage assembly 150 includes a first motor 158A operatively coupled to a first side of the set of linear stages to move the first linear stage 156A of the set of linear stages in the first direction and a second motor 158B operatively coupled to a second side of the set of the linear stages to move the second linear stage 156B of the set of linear stages in a second direction. The second direction may be orthogonal (e.g., at a right angle) to the first direction.

In some embodiments, the first motor 158A is operatively coupled to the first linear stage 156A, and the second motor 158B is operatively coupled to the second linear stage 158B. The first motor 158A may move the first linear stage 156A in the first direction, and the second motor 158B may move the second linear stage 156B in the second direction. The first motor 158A and the second motor 158B may move the first linear stage 156A and the second linear stage 158B, respectively, responsive to control logic determining an offset value of the substrate (e.g., how far from center the substrate is in the first and/or second direction). The control logic may determine the offset value of the substrate based on a radius of the substrate and an edge location of the substrate. The control logic may receive the edge location of one or more edges of the substrate from the camera systems 140A and 140B.

In some embodiments, each of the camera systems 140A and 140B may be positioned outside of the chamber 110. In varying embodiments, the camera systems 140A and 140B are positioned below the chamber 110 (e.g., below a substrate) or above the chamber 110 (e.g., above a substrate). In varying embodiments, the camera systems 140A and 140B are positioned on an opposite side of the chamber 110 from the linear stage assembly 150 or on a same side of the chamber 110 as the linear stage assembly 150.

The camera systems 140A and 140B may include a first camera system 140A and a second camera system 140B, each including a sensor. In some embodiments, the first camera system 140A is configured to measure a first edge location of the substrate along the first direction, and the second camera system 140B is configured to measure a second edge location of the substrate along the second direction. The first edge location and the second edge location may be components of an edge location value. The first edge location and the second edge location may be provided to the control logic 104 to determine the offset value. The first edge location may be provided to the control logic 104 with which to determine a first offset value and the second edge location may be provided to the control logic with which to determine a second offset value.

In some embodiments, the linear stage assembly 150 may move the heater 130 in the first direction by the first offset value and in the second direction by the second offset value in order to center the heater 130 above the substrate on the substrate support 120. In some embodiments, the linear stage 150 moves the heater 130 in the first direction and/or the second direction such that the bevel of the substrate is within approximately 0.05 millimeters (mm) to 0.50 mm of an outer edge of the heater 130. In some embodiments, the linear stage 150 may move the heater 130 in the first direction and/or the second direction by approximately 0.0001 mm to 5.0 mm. While the camera systems 140A and B (and the associated one or more sensors) are described here, some embodiments may include a two-dimensional laser profiler with a sensor that provides substantially similar edge location data as the camera systems 140A and 140B.

To determine the offset value of the substrate, the control logic 104 may compare the first edge location and the second edge location with the radius of the substrate. The control logic 104 may receive the radius of the substrate from a slit valve 170, through which the substrate may enter the chamber 110. In some embodiments, the slit valve 170 has a local center finder (LCF) sensor that provides the radius of the substrate to the control logic 104. In some embodiments, the control logic 104 determines the offset value of the substrate based on a difference between the edge location value (e.g., the edge location value determined by the camera systems 140A and 140B), and the radius provided by the local center finder sensor of the slit valve 170.

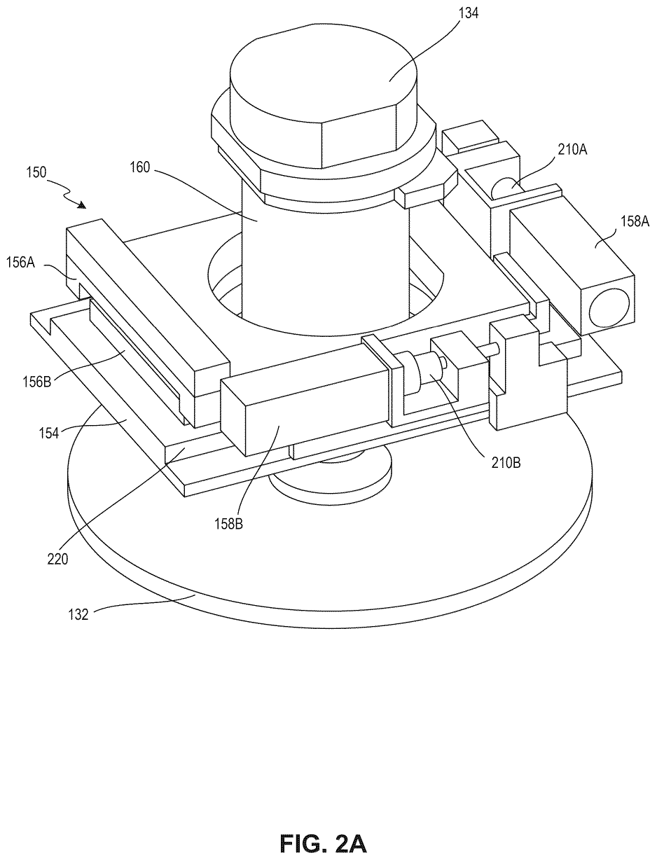

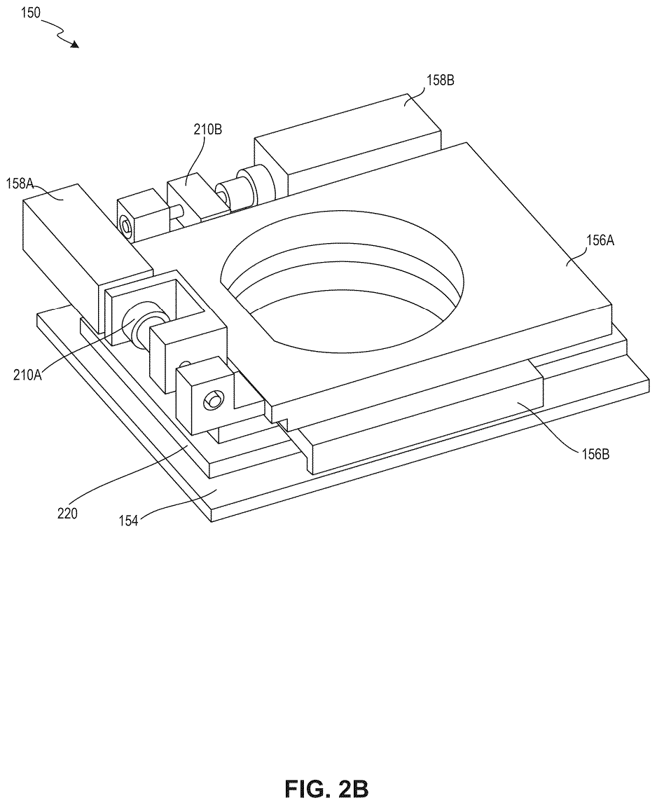

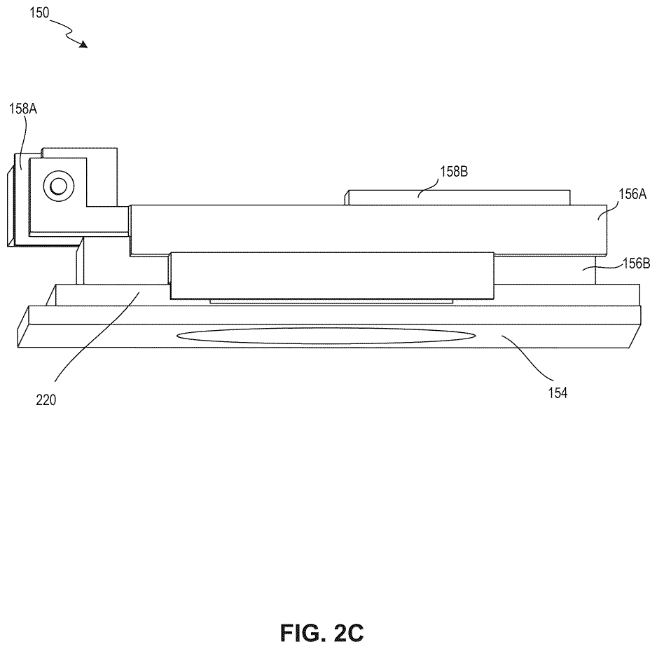

FIG. 2A is a perspective view of a heater (e.g., the heater 130 of FIG. 1A), including the linear stage assembly 150, according to some embodiments. FIG. 2B is a perspective view of the linear stage assembly 150 according to some embodiments. FIG. 2C is a front perspective view of the linear stage assembly 150 according to some embodiments. Both FIGS. 2B and 2C show substantially similar components as those illustrated in FIG. 2A, but from slightly different perspectives.

In some embodiments, the heater 130 includes the radiation surface 132 configured to extend into and be disposed within a chamber (e.g., the chamber 110 of FIG. 1A). The heater 130 may be coupled to the heater lift (e.g., the heater lift 136 of FIG. 1B) via the heater adapter 134, which may further be coupled to the bellow 160. The bellow 160 may encase the heater 130 and maintain a vacuum around the heater 130 and in the chamber, as well as isolate the heater 130 from the linear stage 150.

The linear stage assembly 150 may include the base plate 154, the first linear stage 156A, and the second linear stage 156B. The second linear stage may be moveably coupled between the first linear stage 156A and the base plate 154 via a base plate slide 220. The base plate slide 220 may provide a guiding mechanism (e.g., a glide surface) to the second linear stage 156B, such that the second linear stage 156B may move along the base plate slide 220 in the second direction.

The second linear stage 156B may be coupled to the second motor 158B via a second actuator 210B. The second actuator 210B may translate the electrical energy generated by the second motor 158B into kinetic motion, and may be configured to move the second linear stage 156B in the second direction. Similarly, the first linear stage 156A may be coupled to the first motor 158A via a first actuator 210A, which is configured to move the first linear stage 156A in the first direction.

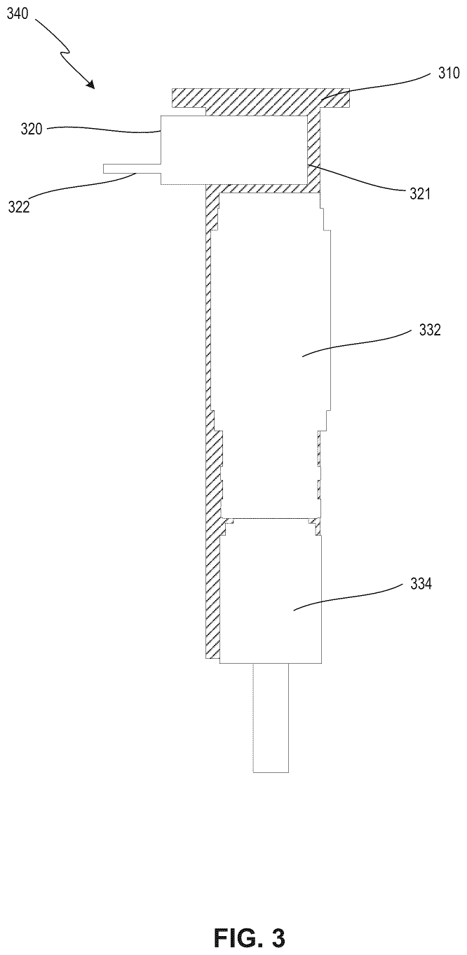

FIG. 3 is a cross-section view of a camera system 340 according to some embodiments. In some embodiments, the camera system 340 is the camera system 140 discussed previously. The camera system 340 may be coupled to a chamber (e.g., the chamber 110 of FIG. 1A) via a housing 310. In some embodiments, the camera system 340 includes the housing 310, a coaxial light system 320, a sensor 334, and a lens 332 coupled between the sensor 334 and the light system 320. The sensor 334 can be a sensor, camera, photodetector, or other image detection device.

The coaxial light system 320 may include a half mirror 321 to allow light from a light source 322 to be delivered to a substrate via a small view port that traverses through a body (e.g., wall) of the chamber and/or through a substrate support (e.g., the substrate support 120 of FIG. 1A), as is better seen in FIGS. 4A-4B and FIG. 4D. For example, the half mirror 321 may allow the light source 322 to be positioned outside the housing 310 and oriented orthogonally to the light path that aligns with a sensor axis, for example, due to the light reflecting off of the half mirror 321. In some embodiments, light from the coaxial light system 320 passes through the view port (e.g., the view port 420 of FIG. 4D) after reflecting off the half mirror 321 and reflects back to the sensor 334 of the camera system 340 with minimal scattering over long distances and/or through narrow passages.

The sensor 334 may be a complementary metal-oxide-semiconductor (CMOS) sensor. In some embodiments, the sensor 334 of the camera system 330 may have a resolution approximately one-fifth that of a target accuracy. For example, if the target accuracy of the camera system 330 is 0.05 mm, the resolution of the sensor 334 is approximately 20 pixels per mm (e.g., resolution=(1 pixel/accuracy in mm)=(1 pixel/0.05 mm)=20 pixels per mm). In some embodiments, the sensor 334 may have a resolution of approximately 10 μm (e.g., 100 pixels per mm).

FIG. 4A is a cross-section view of a portion of the example processing system 100 with a substrate 122 elevated below the heater 130 according to some embodiments. The substrate 122 may be elevated above the substrate support 120 via one or more lift pins 410A and 410B. The one or more lift pins 410A and 410B may receive the substrate 122 via a slit valve (e.g., the slit valve 170 of FIG. 1B).

The processing system 100 may include the one or more camera systems 340 each having a lens 332 and a sensor 334. The processing system 100 can further include one or more view ports 420A and 420B, each coupled to a respective coaxial light system 320. In some embodiments, the camera systems 340 and the accompanying view ports 420A and 420B may be outside of the chamber 110. In some embodiments, the view ports 420A and 420B traverse through the body or wall of the chamber 110. In embodiments, the view ports 420A and 420B may traverse through the substrate support 120 as well when the camera systems 304 are located on the other side of the substrate support 120 from the substrate. In some embodiments, each view port 420A and/or 420B is a clear view port that is small (e.g., approximately 3 mm to 5 mm in diameter) so as to not interfere with substrate processing.

FIG. 4B is the cross-section view of the portion of the example processing system 100 with the substrate 122 lowered on the substrate support 120 according to some embodiments. The one or more lift pins 410 may retract into the substrate support 120 and lower the substrate 122 onto the substrate support 120.

FIG. 4C is a zoomed-in view of a lift pin 410 retracting below the substrate support 120 according to some embodiments. Once the lift pin 410 completely retracts below a top surface of the substrate support 120, the one or more sensors 334 may receive a signal to image one or more edges of the substrate 122, e.g., each sensor 334 may image a separate edge so as to determine a degree of being off-centered in both the X-axis and Y-axis directions. The image of the one or more edges of the substrate 122 are described in further detail in FIG. 4D.

FIG. 4D is a zoomed-in view of a view port 420 that provides an imaging channel to an edge of the substrate support 120 and example image data 450 of off-centered edge locations of the substrate 122 according to some embodiments. The camera system 340 may image an edge location of the substrate 122 via the view port 420. The view port 420 may include one or more grid markings configured to display a radius of the substrate 122. For example, the substrate edge may be visible at a particular grid marking indicating whether the edge is too far or too short of an expected position. In some embodiments, by way of example for purposes of explanation, the radius of the substrate 122 having a diameter of 300 mm is 150 mm. The central grid line 452 may therefore designate a 150 mm radius. The image data 450 may further capture a variance area 454 that displays approximately 1.5 mm on either side of the central grid line 452. The entire image data 450 may be circumscribed within a view area 456, which is approximately 4.0 mm in diameter in some embodiments. Different sizes of substrates and different ranges of actual values of the variance area 454 are envisioned in varying embodiments.

In some embodiments, the sensors 334 may capture image data 450 to determine the offset value (e.g., how far removed the edge of the substrate 122 is from the central grid line 452). The one or more sensors may then transmit the offset value to control logic (e.g., the control logic 104 of FIG. 1A) to move a linear stage assembly (e.g., the linear stage assembly 150 of FIG. 1A) by the offset value. The offset value may include a first offset value and a second offset value. In some embodiments, the one or more sensors may include two sensors that provide the first offset value and the second offset value to the control logic to move the linear stage by the first offset value in the first direction and by the second offset value in the second direction.

For example, the offset value of the substrate may be determined by the difference between the radius of the substrate and the measurement observed via the image data 450. In some embodiments, by way of example for purposes of explanation, the image data 450 may include a grid marking designating a measurement of 148 mm, 150 mm (e.g., the central grid line 452), and 152 mm. In this example, the offset value may be the difference between the radius of the substrate (e.g., 150 mm) and the measurement as indicated by the grid markings in the area 456 (e.g., 151.3 mm in the top image data and 149.5 mm in the bottom image data). Therefore, the first offset value for this particular example may be 1.3 mm in the first direction, and the second offset value may be 0.5 mm in the second direction. In some embodiments, a substrate not being aligned with the central grid line 452 indicates that the substrate is off-centered, and the offset value is needed to determine how much the linear stage assembly 150 should move the heater 130 in the first direction and/or the second direction.

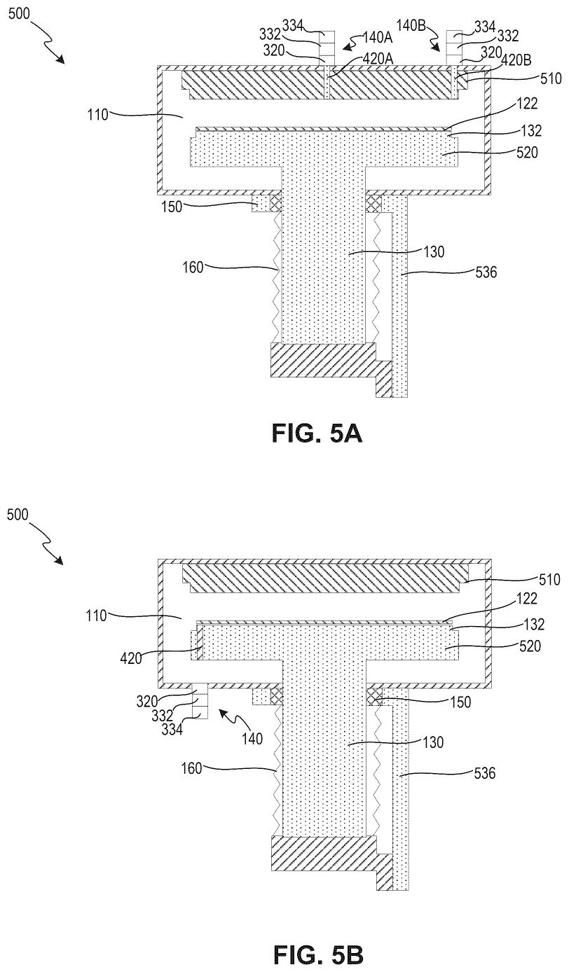

FIG. 5A is a cross-section view of an example processing system 500 with a heater and substrate support combination 520 positioned below a showerhead 510 and one or more camera systems 140A and 140B positioned above the showerhead 510 according to some embodiments. FIG. 5B is a cross-section view of an example processing system 500 with a heater and substrate support combination 520 positioned below a showerhead 510 and one or more camera systems 140A and 140B positioned below the heater and substrate support combination 520 according to some embodiments. In some embodiments, the processing system 500 includes the chamber 110, the showerhead 510, the heater and substrate support combination 520, one or more camera systems 140A and 140B, the heater and substrate support combination lift 536, and the bellow 160.

In some embodiments, the chamber 110 includes the showerhead 510 positioned at the top of the chamber 110 and the heater and substrate support combination 520 including the radiation surface 132 positioned below the showerhead 510. The heater and substrate support combination 520 may be a substrate support with a heater integrated into the substrate support. The heater and substrate support combination 520 may be movable up and down relative to the showerhead 510 via the heater and substrate support combination lift 536. The heater and substrate support combination lift 536 may be the heater lift 136 of FIG. 1B and may be coupled to the linear stage assembly 150.

The linear stage assembly 150 may move in the first direction and/or the second direction responsive to edge location data received by the control logic from the one or more camera systems 140A and 140B. Each of the camera systems may include a lens 332 and a sensor 334 coupled to a coaxial light system 320. The camera systems 140A and 140B may image the edges of the substrate 122 via one or more view ports 420A and 420B. In some embodiments, the camera systems 140A and 140B are positioned above the chamber 110 and above the showerhead 510, with the view ports 420A and 420B traversing through the showerhead 510 to image the substrate 122 on the heater and substrate support combination 520. In some embodiments, the camera systems 140A and 140B are positioned below the chamber 110 and below the heater and substrate support combination 520, with the view port 420 traversing through the heater and substrate support combination 520 to image the substrate 122.

The camera systems 140A and 140B may provide the edge location of the substrate 122 to the control logic 104. The control logic 104 may then determine an offset value of the substrate 122 based on the edge location and the radius of the substrate. The control logic 104 may then cause the linear stage assembly 150 to move in the first direction and/or the second direction by the offset value to center the heater and substrate support assembly 520 below the showerhead 510.

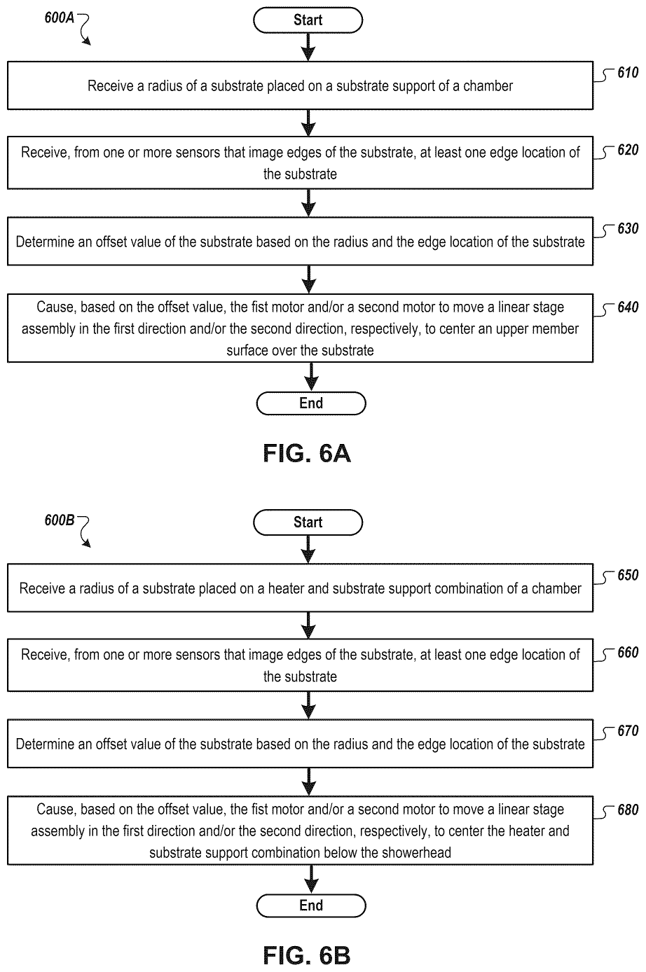

FIG. 6A is a flow chart of an example methods 600A for determining an offset for use by a linear stage in centering a heater above a substrate, according to some embodiments. The method 600A may be performed by processing logic (e.g., control logic, processing device) that may include hardware (circuitry, dedicated logic, etc.), software (such as is run on a general purpose computer system or a dedicated machine), firmware, or some combination thereof. In some embodiments, the method 600A is performed or directed by the control logic 104 of FIG. 1A. Although shown in a particular sequence or order, unless otherwise specified, the order of the processes can be modified. Thus, the illustrated embodiments should be understood as examples, and the illustrated processes can be performed in a different order, and some processes can be performed in parallel. Additionally, one or more processes can be omitted in various embodiments. Thus, not all processes are performed in every embodiment. Other process flows are possible.

At operation 610, the processing logic receives a radius of a substrate placed on a substrate support of a chamber. The processing logic may be coupled to a first motor and a second motor of a linear stage assembly that is operatively coupled to a heater. The heater may have a radiation surface and may be movable up and down relative to the substrate support.

At operation 620, a processing logic receives, from one or more sensors that image edges of the substrate, at least one edge location of the substrate. In some embodiments, the one or more sensors are positioned outside of the chamber. In some embodiments, the one or more sensors are positioned below the heater. The one or more sensors may be positioned within the camera systems 140A and 140B of FIG. 1B, as was discussed previously.

At operation 630, the processing logic determines an offset value of the substrate based on the radius and the edge location of the substrate.

In some embodiments, a first sensor of the one or more sensors measures a first edge location of the substrate along the first direction. The second sensor of the one or more sensors may measure a second edge location of the substrate along the second direction. The offset value may include a first offset value of the first edge location along the first direction and a second offset value of the second edge location along the second direction.

In some embodiments, determining the offset value further includes receiving, from a local center finder sensor, the radius of the substrate. The processing device may further determine a difference between a value of the edge location of the substrate and the radius of the substrate to determine the offset value.

At operation 640, the processing logic causes, based on the offset value, the first motor and/or the second motor to move the linear stage assembly in the first direction and/or the second direction, respectively, to center the upper member surface (e.g., the radiation surface) over the substrate.

In some embodiments, the processing logic causes the first motor to move a first linear stage of the linear stage assembly the first offset value in the first direction and the second motor to move a second linear stage of the linear stage assembly the second offset value in the second direction. In some embodiments, the first direction is orthogonal to the second direction.

FIG. 6B is a flow chart of an example method 600B for determining the offset for use in controlling the linear stage to center a heater and substrate support combination below a showerhead according to some embodiments. The method 600B may be performed by processing logic (e.g., control logic, processing device) that may include hardware (circuitry, dedicated logic, etc.), software (such as is run on a general purpose computer system or a dedicated machine), firmware, or some combination thereof. In some embodiments, the method 600B is performed or directed by the control logic 104 of FIG. 1A. Although shown in a particular sequence or order, unless otherwise specified, the order of the processes can be modified. Thus, the illustrated embodiments should be understood as examples, and the illustrated processes can be performed in a different order, and some processes can be performed in parallel. Additionally, one or more processes can be omitted in various embodiments. Thus, not all processes are performed in every embodiment. Other process flows are possible.

At operation 650, the processing logic receives a radius of a substrate placed on the heater and substrate support combination of a chamber. The processing logic may be coupled to a first motor and a second motor of a linear stage assembly that is operatively coupled to the heater and substrate support combination. The heater and substrate support combination may have a radiation surface and may be movable up and down relative to a showerhead positioned at the top of the chamber.

At operation 660, the processing logic receives, from one or more sensors that image edges of the substrate, at least one edge location of the substrate. In some embodiments, the one or more sensors are positioned outside of the chamber. In some embodiments, the one or more sensors are positioned below the chamber and below the heater and substrate support combination. In embodiments, the one or more sensors are positioned above the chamber and above the showerhead. The one or more sensors may be positioned within the camera systems 140A and 140B of FIG. 1B, as was discussed previously.

At operation 670, the processing logic determines an offset value of the substrate based on the radius and the edge location of the substrate.

In some embodiments, a first sensor of the one or more sensors measures a first edge location of the substrate along the first direction. The second sensor of the one or more sensors may measure a second edge location of the substrate along the second direction. The offset value may include a first offset value of the first edge location along the first direction and a second offset value of the second edge location along the second direction.

In some embodiments, determining the offset value further includes receiving, from a local center finder sensor, the radius of the substrate. The processing device may further determine a difference between a value of the edge location of the substrate and the radius of the substrate to determine the offset value.

At operation 680, the processing logic causes, based on the offset value, the first motor and/or the second motor to move the linear stage assembly in the first direction and/or the second direction, respectively, to center the heater and substrate support combination below the showerhead.

In some embodiments, the processing logic causes the first motor to move a first linear stage of the linear stage assembly the first offset value in the first direction and the second motor to move a second linear stage of the linear stage assembly the second offset value in the second direction. In some embodiments, the first direction is orthogonal to the second direction.

The preceding description sets forth numerous specific details such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular implementations may vary from these exemplary details and still be contemplated to be within the scope of the present disclosure.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A system comprising:
a chamber comprising a substrate support;
an upper member comprising an upper member surface positioned within the chamber and being movable up and down relative to the substrate support;
one or more sensors, each configured to measure an edge location of a substrate placed on the substrate support;
a linear stage assembly coupled to the upper member and comprising:
a set of linear stages;
a first motor operatively coupled to a first side of the set of linear stages to move a first linear stage of the set of linear stages in a first direction; and
a second motor operatively coupled to a second side of the set of linear stages to move a second linear stage of the set of linear stages in a second direction; and
control logic operatively coupled to the one or more sensors, the first motor, and the second motor, wherein the control logic is to:
receive the edge location from the one or more sensors;
determine, based on a radius of the substrate, an offset value of the substrate relative to the edge location; and
control, using the offset value, at least one of the first motor or the second motor to center the upper member surface over the substrate.

2. The system of claim 1, wherein the upper member is a heater and the upper member surface is a radiation surface.

3. The system of claim 1, wherein the second side is adjacent to the first side of the set of linear stages and wherein the first direction is orthogonal to the second direction.

4. The system of claim 1, wherein, to determine the offset value, the control logic is to:
receive, from a local center finder sensor, the radius of the substrate; and
determine a difference between a value of the edge location and the radius.

5. The system of claim 1, wherein the one or more sensors comprises a first sensor to measure a first edge location of the substrate along the first direction and a second sensor to measure a second edge location of the substrate along the second direction, and wherein the offset value comprises a first offset value of the first edge location along the first direction and a second offset value of the second edge location along the second direction.

6. The system of claim 5, wherein the control logic is to cause:
the first motor to move the first linear stage the first offset value in the first direction; and
the second motor to move the second linear stage the second offset value in the second direction.

7. The system of claim 1, further comprising:
a first actuator attached between the first motor and the first linear stage; and
a second actuator attached between the second motor and the second linear stage.

8. The system of claim 1, further comprising:
a lift positioned outside the chamber, wherein the lift is attached to the upper member and the linear stage assembly, and is configured to move the upper member up and down; and
a bellow surrounding the upper member and attached between a lid of the chamber and an adapter of the upper member, wherein the adapter is attached to the lift, and the bellow is to maintain a vacuum around the upper member.

9. The system of claim 1, wherein the linear stage assembly further comprises:
a base plate attached to a lid of the chamber;
the first linear stage attached to the first motor, wherein the first linear stage is moveable in the first direction; and
the second linear stage attached to the second motor and moveably coupled between the first linear stage and the base plate, wherein the second linear stage is moveable in the second direction.

10. The system of claim 1, wherein each sensor of the one or more sensors is a component of a camera system, which further comprises:
a coaxial light system comprising a half mirror configured to deliver light to the substrate via a view port that passes through a portion of the chamber; and
a lens coupled between the sensor and the coaxial light system.

11. The system of claim 1, wherein each of the one or more sensors is a sensor of a two-dimensional laser profiler.

12. The system of claim 1, wherein the one or more sensors are positioned outside of the chamber and on an opposite side of the chamber from the linear stage assembly.

13. A method comprising:
receiving, by a processing device, a radius of a substrate placed on a substrate support of a chamber, wherein the processing device is coupled to a first motor and a second motor of a linear stage assembly that is operatively coupled to an upper member, and wherein an upper member surface is movable up and down relative to the substrate support;
receiving, from one or more sensors that image edges of the substrate, at least one edge location of the substrate;
determining an offset value of the substrate based on the radius and the edge location of the substrate; and
causing, by the processing device, based on the offset value, at least one of the first motor or the second motor to move the linear stage assembly in at least one of a first direction or a second direction, respectively, to center the upper member surface over the substrate.

14. The method of claim 13, further comprising:
measuring, with a first sensor of the one or more sensors, a first edge location of the substrate along the first direction; and
measuring, with a second sensor of the one or more sensors, a second edge location of the substrate along the second direction;
wherein the offset value comprises a first offset value of the first edge location along the first direction and a second offset value of the second edge location along the second direction.

15. The method of claim 14, further comprising:
causing the first motor to move a first linear stage of the linear stage assembly the first offset value in the first direction; and
causing the second motor to move a second linear stage of the linear stage assembly the second offset value in the second direction, wherein the first direction is orthogonal to the second direction.

16. The method of claim 13, wherein determining the offset value comprises:
receiving, from a local center finder sensor, the radius of the substrate; and
determining a difference between a value of the edge location and the radius.

17. A system comprising:
a chamber comprising a showerhead;
a heater comprising a radiation surface positioned within the chamber and being movable up and down relative to the showerhead;
one or more sensors, each configured to measure an edge location of a substrate placed on the radiation surface;
a linear stage assembly coupled to the heater and comprising:
a set of linear stages;
a first motor operatively coupled to a first side of the set of linear stages to move a first linear stage of the set of linear stages in a first direction; and
a second motor operatively coupled to a second side of the set of linear stages to move a second linear stage of the set of linear stages in a second direction, wherein the second side is adjacent to the first side of the set of linear stages and wherein the first direction is orthogonal to the second direction; and
control logic operatively coupled to the one or more sensors, the first motor, and the second motor, wherein the control logic is to:
receive the edge location from the one or more sensors;
determine, based on a radius of the substrate, an offset value of the substrate relative to the edge location; and
control, using the offset value, at least one of the first motor or the second motor to center the substrate below the showerhead.

18. The system of claim 17, wherein the second side is adjacent to the first side of the set of linear stages and wherein the first direction is orthogonal to the second direction.

19. The system of claim 17, wherein, to determine the offset value, the control logic is to:
receive, from a local center finder, the radius of the substrate; and
determine a difference between a value of the edge location and the radius.

20. The system of claim 17, wherein the one or more sensors comprises a first sensor to measure a first edge location of the substrate along the first direction and a second sensor to measure a second edge location of the substrate along the second direction, wherein the offset value comprises a first offset value of the first edge location along the first direction and a second offset value of the second edge location along the second direction, and wherein the control logic is to cause:
the first motor to move the first linear stage the first offset value in the first direction; and
the second motor to move the second linear stage the second offset value in the second direction.

21. The system of claim 17, further comprising:
a lift positioned outside the chamber, wherein the lift is attached to the heater and the linear stage assembly, and is configured to move the heater up and down; and
a bellow surrounding the heater and attached between a lid of the chamber and an adapter of the heater, wherein the adapter is attached to the lift, and the bellow is to maintain a vacuum around the heater.
